(19) United States
(12) Patent Application Publication
(10) Pub. No.: US 2021/0328201 A1
(43) Pub. Date: Oct. 21, 2021

(54) Mask Plate and Manufacturing Method Thereof, Method for Forming A Film Layer, and Encapsulation Structure

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Da ZHOU, Beijing (CN); Zhiliang JIANG, Beijing (CN); Zailong MO, Beijing (CN); Xuefeng LV, Beijing (CN)

(21) Appl. No.: 16/338,105

(22) PCT Filed: Nov. 13, 2018
(86) PCT No.: PCT/CN2018/115159

§ 371 Date: Mar. 29, 2019

(30) Foreign Application Priority Data
Jan. 4, 2018 (CN) 201810008037.7

(51) Int. Cl. H01L 51/56; H01L 27/32; H01L 51/52

(52) U.S. Cl. CPC H01L 51/56; H01L 51/5237; H01L 27/3244; H01L 27/3283

(57) ABSTRACT

A mask plate is provided to be divided into at least a transmissive region and a shading region. The mask plate includes a main body and a projection structure disposed on the main body at an edge of the shading region adjacent to the transmissive region; and the projection structure protrudes away from the main body, and a thickness of the projection structure in a direction perpendicular to a plane of the main body decreases gradually in a direction from the transmissive region to the shading region. The mask plate of the present disclosure can prevent the broken deposits formed in the vapor deposition process from peeling off, reduce the deposition shadow, and prolong the service time of the mask plate, thereby improving the productivity and reducing the cost.

### CROSS-REFERENCE TO RELATED APPLICATION

The present application claims the priority to the Chinese Patent Application No. 2018100080.7.7 filed to State Intellectual Property Office of the Republic of China on Jan. 4, 2018, titled “Mask plate and Manufacturing Method thereof, Method for forming a film layer, and Encapsulation Structure”, the contents of which is hereby incorporated by reference in its entirety.

### TECHNICAL FIELD

The present disclosure relates to the field of display technology, in particular, to a mask plate, a method for manufacturing a mask plate, a method for forming a film layer, and an encapsulation structure.

### BACKGROUND

An OLED (Organic Light-Emitting Diode) display device is one of the commonly used flat panel display devices at present. Thin Film Encapsulation (TFE) is a key technology for realizing OLED display. In the flexible OLED process, it is necessary to perform an encapsulation process for water-oxygen blocking after the evaporation of the organic material of the OLED device is completed.

In the encapsulation process, in order to reduce the Water Oxygen Vapor Transmission (WVTR), a superimposed multilayer encapsulation including a first inorganic film layer, an organic film layer, and a second inorganic film layer is widely adopted. FIGS. 1A and 1B are a top view and a cross-sectional view of a conventional mask plate, respectively. However, as shown in FIG. 2, such a mask plate inevitably causes deposits 2 to be deposited at an edge of a mask plate in a chemical vapor deposition (CVD) process, thus a deposition shadow 21 (a region formed by the actual deposition boundary exceeding the boundary of the mask plate) is formed. Moreover, due to the limitation of the vapor deposition process level and the mask plate size accuracy, a first inorganic film layer and a second inorganic film layer are deposited by using a mask plate designed in the same manner, the deposition shadow together with the alignment deviation of the mask plate may cause the risk of water and oxygen entering the superimposed multilayer encapsulation to rise sharply. As the alignment accuracy of the mask plate decreases, the risk that the deposits formed in the vapor deposition process in the shading region peel off increases as the evaporation time elapses. The peeling-off deposits or foreign matter may directly damage the encapsulation film layer, resulting in failure of the film encapsulation, and further reducing the film encapsulation performance. In addition, the increased peeling-off deposits reduce the clean cycle of the mask plate, reducing the productivity and increasing the production cost.

### SUMMARY

In view of the above disadvantages in the related art, the present disclosure provides a mask plate, a method for manufacturing a mask plate, a method for forming a film layer, and an encapsulation structure which can reduce the deposition shadow and effectively avoid the alignment deviation of the encapsulation film layers due to the process.

One aspect of the present disclosure is to provide a mask plate, which is divided into at least a transmissive region and at least a shading region, the mask plate includes a main body and a projection structure disposed on the main body and at an edge of the shading region adjacent to the transmissive region; and the projection structure protrudes away from the main body, and a thickness of the projection structure in a direction perpendicular to a plane of the main body decreases gradually in a direction from the transmissive region to the shading region.

Optionally, a cross section of the projection structure in a plane perpendicular to the plane of the main body and in a direction from the transmissive region to the shading region has a shape of a triangle or a trapezoid.

Optionally, the projection structure comprises a slope in a direction from the transmissive region to the shading region on a plane perpendicular to the plane of the main body, the slope being a smooth curved surface.

Optionally, the projection structure further includes a flat portion adjacent to the transmissive region, and a thickness of the flat portion corresponds to a maximum thickness of the projection structure.

Optionally, the projection structure extends towards the transmissive region to form an extension portion which is suspended above the transmissive region.

Optionally, the projection structure extends towards the transmissive region to form an extension portion which comprises two slopes in a direction from the shading region to the transmissive region on a plane perpendicular to the plane of the main body.

Optionally, the two slopes are two curved surfaces which are symmetrical in a horizontal direction.

Optionally, in a direction from the shading region to the transmissive region, a size of the extension portion of the projection structure which is suspended above the transmissive region ranging from ¼ to ½ of a total size of the projection structure in this direction.

A method for manufacturing a mask plate, the mask plate being divided into at least a transmissive region and a shading region, and the mask plate includes a main body and a projection structure disposed on the main body and at an edge of the shading region adjacent to the transmissive region; and the projection structure protrudes away from the main body, and a thickness of the projection structure in a direction perpendicular to a plane of the main body decreases gradually in a direction from the transmissive region to the shading region, the method including steps of:

dividing a base block into at least a transmissive region section corresponding to the transmissive region of the mask plate and a shading region section corresponding to a shading region of the mask plate;

performing a first patterning process on the base block such that a height of the transmissive region section is greater than a height of the shading region section where the projection structure is not disposed, the base block having a slope structure which is tapered from the transmissive region section to the shading region section where the projection structure is not be disposed, and

removing at least a part of the transmissive region section by a second patterning process.

Optionally, the step of removing at least a part of the transmissive region section by a second patterning process comprises completely removing the transmissive region section by the second patterning process.

Optionally, the first patterning process includes:

coating photoresist on a front side of the base block and performing exposing and developing on the photoresist by using a gray-tone reticle plate or a half-tone reticle plate to reserve a portion of the photoresist in a first complete-reservation region corresponding to the transmissive region section, and remove a portion of the photoresist in a first complete-removal region corresponding to the part of the shading region where the projection structure is not to be disposed, and cause a portion of the photoresist in a half-reservation region corresponding to the projection structure to form a slope with a thickness decreasing gradually from an initial thickness of the photoresist in the first complete-reservation region to zero;

performing a dry etching process on the base block to obtain a shape that is thinner at two sides and has an original thickness in a middle and slopes from the middle of the base block to the two ends; and

removing the photoresist on the base block.

Optionally, the first patterning process includes:

coating photoresist on a front side of the base block and performing exposing and developing on the photoresist by using a first reticle plate to reserve a portion of the photoresist in a first reservation region corresponding to the transmissive region of the mask plate and remove a portion of the photoresist in a first transmissive region corresponding to the shading region of the mask plate;

performing a hard baking process on the photoresist such that an edge of the reserved portion of the photoresist shrinks to form a slope so as to obtain a shape that is thinner at both ends, and has an original thickness in a middle and slopes from the middle to the two ends; dry etching the base block; and

removing the photoresist.

Optionally, the first patterning process includes:

coating photoresist on a front side of the base block and performing exposing and developing on the photoresist by using a first reticle plate to reserve a portion of the photoresist in a first reservation region corresponding to the transmissive region of the mask plate and removing a portion of the photoresist in a first removal region corresponding to the shading region of the mask plate;

performing a wet etching process on the base block so that portions of the base block at the first removal region have arc-shaped surfaces, respectively; and

removing the photoresist.

Optionally, the second patterning process includes: making a part of the base block corresponding to the transmissive region remain a thickness less than or equal to a thickness of the main body; then performing a third patterning process on a backside surface of the base block on which the projection structure is not formed to completely remove the part of the base block corresponding to the transmissive region section.

Optionally, both the second patterning process and the third patterning process comprise a wet etching process.

Optionally, the second patterning process includes: forming a notch on the transmissive region section of the base block such that the notch has a size along an extension direction of the main body which is obtained by subtracting extension distances of two opposite projection structures extending into the transmissive region from a span of the transmissive region along the extension direction of the main body, and

the third patterning process includes: forming an opening having a size of the span of the transmissive region along the extension direction of the main body such that the projection structure extends to the transmissive region and is partially suspended above the transmissive region.

A method for forming a film layer in an encapsulation structure, and the film layer including a first inorganic film layer and a second inorganic film layer which are formed by a chemical vapor deposition process, the method including steps of:

forming the first inorganic film layer by using a first mask plate which is divided into at least a first transmissive region and a first shading region, and has a first main body and a first projection structure disposed at an edge of the first shading region adjacent to the first transmissive region and extending in a direction perpendicular to a plane of the first main body;

forming an organic film layer; and

forming the second inorganic film layer by using a second mask plate which is divided into at least a second transmissive region and a second shading region, and has a second main body and a second projection structure disposed at the edge of the second shading region adjacent to the second transmissive region and extending in the direction perpendicular to the plane of the second main body;

wherein a height of a part of the first projection structure near the first transmissive region is greater than that of a part of the first projection structure away from the first transmissive region, and a height of a part of the second projection structure near the second transmissive region is greater than that of a part of the second projection structure away from the second transmissive region.

Optionally, a maximum height of the first projection structure is greater than that of the second projection structure.

An encapsulation structure includes a first inorganic film layer and a second inorganic film layer which are formed by the above method for forming a film layer.

The beneficial effects of the present disclosure are as follows.

The mask plate can effectively prevent the broken deposits formed in the vapor deposition process from peeling off, thus effectively prevent the peeling-off deposits from contaminating the substrate. The mask plate also can reduce the deposition shadow, prolong the replacement time of the mask plate within an evaporation cycle, which further improve the productivity and reduce the cost.

The method for forming a film layer utilizes a mask plate having a sheltering angle (a sheltering angle in this specification is defined as the height of the projection structure or the height of the mask plate adjacent to the transmissive region) adapted to control the deposition shadow, and the range of the deposition shadow is adjusted by adjusting a height of the projection structure so as to make the deposition angle be matched with the sheltering angle of the thin film encapsulation structure (TFE), which can prevent effectively the peeling-off deposits from contaminating the substrate.

In the encapsulation structure, an increased margin is achieved, so that the alignment margin for aligning the first inorganic film layer with the second inorganic film layer is further improved with the aperture ratio unchanged, thereby improving the reliability of the thin film encapsulation, especially the narrow bezel encapsulation.

### BRIEF DESCRIPTION OF THE FIGURES

FIGS. 1A and 1B are a top view and a cross-sectional view of a mask plate of an encapsulation structure in the related art, respectively;

FIG. 2 is a schematic diagram illustrating a manufacturing process for an encapsulation structure in the related art;

FIG. 3 is a schematic diagram of an encapsulation structure in the related art;

FIGS. 4A and 4B are a top view and a cross-sectional view of a mask plate according to an embodiment of the present disclosure, respectively;

FIG. 5 is a schematic diagram illustrating a manufacturing process for an encapsulation structure according to an embodiment of the present disclosure;

FIGS. 6A to 6C are schematic diagrams illustrating a method for manufacturing a mask plate according to embodiments of the present disclosure;

FIGS. 7A and 7B are a top view and a cross-sectional view of a mask plate according to an embodiment of the present disclosure, respectively;

FIGS. 8A to 8C are diagrams of a method for manufacturing a mask plate according to embodiments of the present disclosure;

FIG. 9 is a structural diagram of an encapsulation structure according to an embodiment of the present disclosure;

FIGS. 10A to 10B and 11A to 11B are schematic diagrams illustrating methods for manufacturing encapsulation structure according to embodiments of the present disclosure.

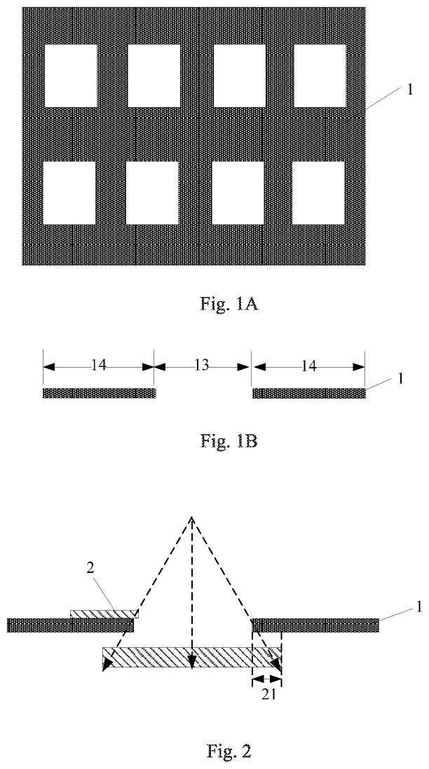

### REFERENCE NUMERALS

1—mask plate; 11—main body; 12—projection structure; 13—transmissive region; 131—notch; 132—opening; 14—shading region;
2—deposits; 21—shadow;
31—photoresist; 32—base block; 33—first reticle plate; 34—second reticle plate;
5—encapsulation structure; 51—first inorganic film layer; 52—organic film layer, 53—second inorganic film layer.

### DETAILED DESCRIPTION

A mask plate, a method for manufacturing a mask plate, a method for forming a film layer and an encapsulation structure of the present disclosure will be further described below in conjunction with specific implementations and the drawings in order that those skilled in the art can understand the technical solutions of the present disclosure better.

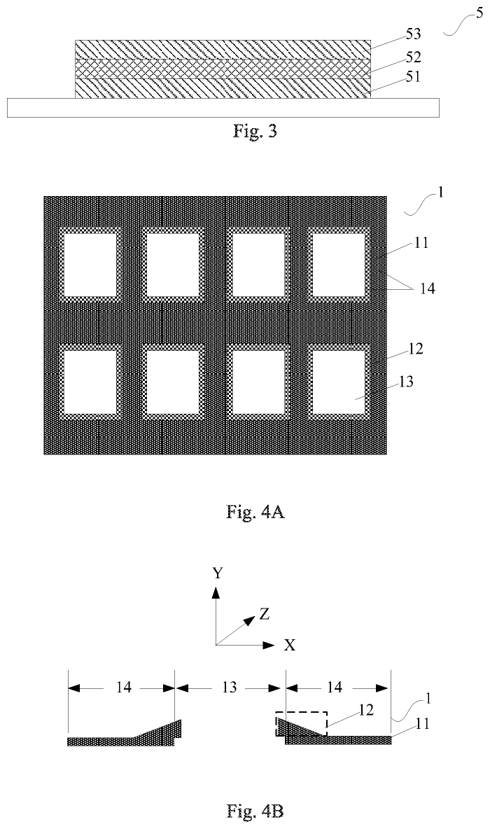

The inventive concept of the present disclosure is as follows: the basic reason for the alignment deviation of the film layers of thin film encapsulation structure is that, the difference in process shadow between the first inorganic film layer and the second inorganic film layer is not distinguished when employing a mask plate to manufacture a thin film encapsulation structure. The first inorganic film layer and the second inorganic film layer are manufactured by using mask plates having the same design to form a thin film encapsulation structure as shown in FIG. 3. The alignment deviation is further increased as the alignment processes for the first inorganic film layer and the second inorganic film layer are different.

Based on the basic reason of the alignment deviation, that is, the reason that the deposition shadows of the first inorganic film layer and the second inorganic film layer arise in the vapor deposition process, the present disclosure designs a mask plate for manufacturing the thin film encapsulation structure which makes the sheltering angle match the deposition angle under the principle that the deposition shadow is combined with the boundary of the encapsulation structure. The mask plate not only avoids the alignment deviation of the film layers in the encapsulation structure caused by the process, but also effectively reduces the contamination to the substrate by the peeling-off deposits, thus improving the film layer performance. Moreover, it also prolongs the replacement time of the mask plate for manufacturing the thin film encapsulation structure within an evaporation cycle, further increasing the productivity and reducing the cost.

Here, the deposition angle is a popular term for the shadow, and is measured by the difference between the ideal sidewall of a film layer and the actual sidewall formed in thin film encapsulation structure. The size of the deposition angle can be simply defined as: a distance from the boundary of the mask plate to the boundary of an encapsulation film layer; or a distance over which the film thickness of the boundary of a film layer in thin film encapsulation structure drops from 95% to 5%.

In view of the problem that the existing mask plate cannot block the peeling-off deposits generated in the vapor deposition process, affecting the quality of the finished product and accelerating the clean cycle, the embodiments of the present disclosure provide a mask plate and a method for manufacturing a mask plate, which can effectively block the peeling-off deposits generated in the vapor deposition process, ensure the quality of the finished product and prolong the clean cycle.

In an embodiment, a film layer in thin film encapsulation structure formed by the chemical vapor deposition is taken as an example. As shown in FIGS. 4A and 4B, the mask plate 1 used for manufacturing the film layer is divided into at least a transmissive region 13 and a shading region 14, and the mask plate includes a main body 11 and a projection structure 12 disposed at an edge of the shading region 14 adjacent to the transmissive region 13 to protrude in a direction perpendicular to the main body 11. A thickness of the projection structure 12 in the direction perpendicular to the main body 11 decreases gradually from the transmissive region 13 to the shading region 14. The transmissive region 13 is an opening region of the mask plate for allowing the deposits to deposit and form a thin film layer.

In FIG. 4B, the plane of the main body 11 is a plane XZ, the height direction of the projection structure 12 corresponds to a direction Y, the direction directed from the transmissive region to the shading region corresponds to a direction X; such definitions apply to the descriptions.

As shown in FIG. 4B which illustrates the cross-sectional view of the mask plate, the main body 11 is generally a regular rectangle and its top surface is a flat surface. The transmissive region 13 corresponds to the opening region of the main body, and the shading region 14 corresponds to the shading region of the main body.

Optionally, a portion of the projection structure 12 adjacent to the edge of the transmissive region is suspended. The projection structure 12 extends to the transmissive region 13 and the extension portion is suspended above the transmissive region. The projection structure 12 can further block the peeling-off deposits, and is especially suitable for a normal bezel. A bezel corresponds to a distance from a boundary of a pixel opening to a trim mark. For example, according to a domestic manufacturer of display products, the width of a normal bezel is defined as >900 μm, and the width of a narrow bezel is defined as <850 μm.

The shading region 14 may be used to block the deposits. In the mask plate 1, the projection structure 12 is provided to form a sheltering angle, which prevents the deposits over the edge portion of the mask plate at the boundary of the shading region 14 from being broken due to gravity. Since the impurities peeling off the mask plate are solid SiOx/SiNx, they may remain in the encapsulation film layer as foreign matter and cause cracks generated in the encapsulation film layer (TFE Cracks). Accordingly, the mask plate can solve the problem that deposits increasingly peel off the shielding region and contaminates non-shading region (i.e., the transmissive region 13) as deposition time increases, which prevents the peeling-off deposits from dropping through the transmissive region 13. Thus, the slope of the sheltering angle is used to reduce a risk of deposits peeling off, and encapsulation effect is guaranteed.

Moreover, a height of an edge of the projection structure 12 proximal to the transmissive region 13 may be adjusted with respect to that of the other edge of the projection structure 12 distal to the transmissive region 13 to form sheltering slopes with different angles. Different slopes can obtain different effects of collecting deposits in the shading region 14 and can further improve the performance of the film layer.

Extending the projection structure 12 in a suspended manner in the mask plate of the present embodiment is different from that of simply reducing the size of the transmissive region. On one hand, downsizing in the transmissive region decreases the pixel aperture ratio (corresponding to the transmissive region of the mask plate), and on the other hand, does not substantially change the shadow, but results in a reduction of an encapsulation area having an effective film thickness greater than 70%.

Optionally, in a direction from the shading region to the transmissive region, a size of the projection structure extending to the transmissive region ranges from ¼ to ½ of a total size of the projection structure in the direction X. For example, according to a domestic manufacturer of display products, a product with a normal bezel of 1060 μm has an extension distance of 350 to 650 μm. With a suitable extension of the projection structure 12 into the transmissive region 13, both blocking and receiving the deposits can be ensured.

To better receive the deposits in a structure, the height of the projection structure 12 decreases gradually in a direction from the transmissive region 13 to the shading region 14. Optionally, a cross section of the projection structure 12 on a plane perpendicular to the plane of the main body 11 and in a direction from the transmissive region to the shading region has a shape of a triangle or a trapezoid. FIG. 4B schematically shows the projection structure 12 with a typical shape. It should be appreciated that, the cross section of the projection structure 12 on a plane perpendicular to the plane of the main body may have any other shape, which is not particularly limited here, as long as it can block the peeling-off deposits generated in the vapor deposition process.

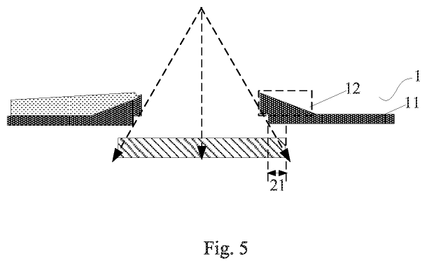

As shown in FIG. 5, the size of the shadow 21 generated by the mask plate 1 during the manufacturing process of the encapsulation structure is reduced significantly compared with the size of the shadow 21 in FIG. 2. The length of the cross section of the film layer of the thin film encapsulation formed in FIG. 5 is less than that of the film layer of the thin film encapsulation formed in FIG. 2.

The evaporation cycle is a time period in which there is a stable temperature in the evaporation chamber between the temperature-rise procedure and the temperature-drop procedure. No evaporation can be performed during both the temperature-rise procedure and the temperature-drop procedure. Evaporation materials account for about 40% of the screen cost. From the perspective of saving the factory cost, each time frame for cleaning the mask plate 1 needs to match the evaporation cycle. Thus, in the industrial process, a timing at which the peeling-off deposits exists on the mask plate for forming the encapsulation structure is usually used as a time frame for cleaning the mask plate. In the mask plate 1 of the present embodiment, since the projection structure 12 is provided, the clean cycle of the mask plate may be prolonged effectively. The mask plate is suitable for a film layer encapsulation structure with a normal bezel and a narrow bezel.

Accordingly, the embodiment further provides a method for manufacturing a mask plate which is used to form a mask plate for manufacturing a film layer structure in vapor deposition process.

The method for manufacturing a mask plate includes a step of dividing the mask plate into at least a transmissive region and a shielding region, wherein a projection structure 12 located at an edge of the shading region 14 adjacent to the transmissive region 13 and disposed in a direction perpendicular to the main body 11 is formed on the main body 11. The height of the projection structure 12 near the transmissive region is greater than that of the projection structure 12 away from the transmissive region.

In a case of a projection structure 12 with a simple shape, the mask plate 1 may be formed integrally in a same process. In a case of a projection structure 12 with a complex shape, the reticle plates need to be modified so that the resulting mask plate to be used to form an encapsulation structure has a function of collecting deposits.

Before explaining a specific manufacturing method, it should be noted that, in the present disclosure, the patterning process may include a photolithography process only, or include a photolithography process and an etching step, and may further include other processes for forming a predetermined pattern, such as printing, inkjet, and the like. The photolithography process refers to a process for forming a pattern by using photoresist, a mask plate, an exposure machine and so on, which includes technological processes such as film formation, exposing, developing, etc. Corresponding patterning processes may be selected according to the structures formed by the different steps in the present disclosure.

The method for manufacturing a mask plate mainly includes two processes of forming a projection structure and forming a transmissive region. The manufacturing method of the present embodiment includes the following steps:

making, by a patterning process, a height of a section of the base block corresponding to the transmissive region greater than a height of a shading region section of the base block where the projection structure is not disposed, the base block corresponding to the projection structure having a slope structure which is tapered from the transmissive region section corresponding to the transmissive region to the shading region section corresponding to the shading region;

Removing, by a patterning process, the part of the base block corresponding to the transmissive region where the projection structure is not disposed, and reserving a part of the base block corresponding to the projection structure and the shading region.

The step for forming the structure with the slope includes: a combination of a semi-exposure process and a dry etching process; or a combination of an exposure process, a hard baking process and a dry etching process; or a combination of an exposure process and a wet etching process.

In an alternative manufacturing method, the mask plate may be manufactured by a method including a combination of a semi-exposure process and a dry etching process as well as a normal exposure process, that is, a first exposure process is the semi-exposure process in which a gray-tone reticle plate or a half-tone reticle plate is used, and a second exposure is the normal exposure process. A section corresponding to the transmissive region 13 is a first complete-reservation region, a section corresponding to the projection structure 12 is a half-reservation region, and a section corresponding to the shading region 14 is a first complete-removal region. The half-reservation region has a transmittance which changes gradually from the first complete-reservation region to the first complete-removal region. A normal reticle plate is used in the second exposure process, a section corresponding to the transmissive region 13 is a second removal region, and a section corresponding to the projection structure 12 and the shading region 14 is a second reservation region.

Here, the terms “reservation region” and “removal region” are termed in regard to whether the photoresist formed therein during a coating process is reserved or removed in a final state, regardless of the properties of the photoresist (e.g. negative photoresist or positive photoresist). Generally, the negative photoresist is reserved while the positive photoresist is removed after the exposure and developing processes.

Meanwhile, the mask plate is formed integrally. That is, the mask plate including a plurality of transmissive region sections and projection structures is formed from a cubic base block. It should be appreciated that, for ease of description, a local structure including one transmissive region shown in FIG. 4A is selected, and one local structure in the mask plate which may be used to form a single separate film layer structure is described (i.e., the structure in FIG. 4A including the transmissive region 13 and the shading region 14 surrounding the transmissive region 13). The terms “two ends”, “terminal”, and “middle” mentioned below are termed relative to such structure.

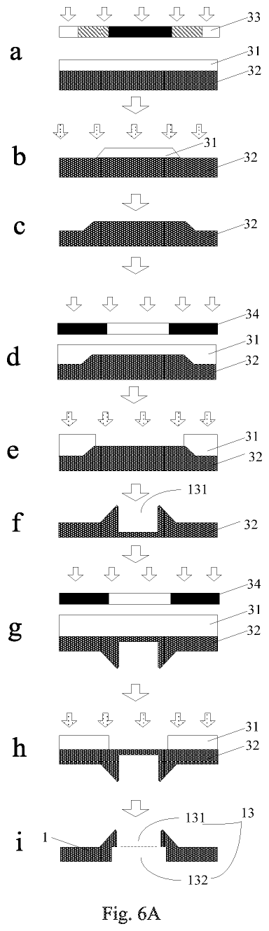

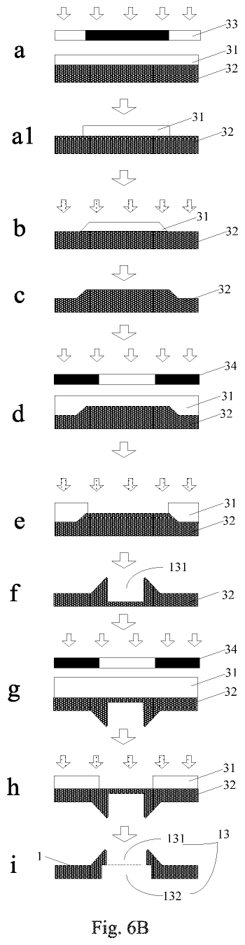

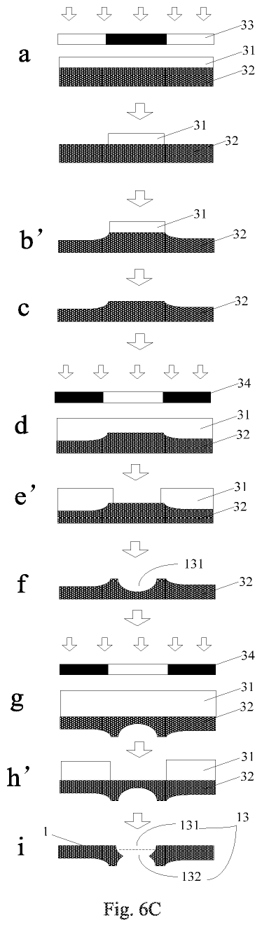

As shown in FIG. 6A, in a step of forming the projection structure:

a. first, coating the photoresist 31 on the front side of the base block 32, and performing exposing by using the first reticle plate 33, i.e., a half-tone or gray-tone reticle plate, reserving the portion of the photoresist 31 in the first complete-reservation region, removing the portion of the photoresist 31 in the first complete-removal region, and making the portion of the photoresist 31 in the half-reservation region form a slope with a thickness decreasing gradually from an initial thickness to zero, and thus achieving a long slope with a mild profile; b. then, dry etching the base block 32 to obtain a prototype with a shape that is thinner at both ends with an original thickness in the middle and is inclined from the middle to two ends, and thus forming a slope (which is also called sheltering-angle) having a conformal profile of the photoresist; c. then, stripping the photoresist 31.

In the step of forming the transmissive region: processing the front side and the back side of the base block 32 respectively, and forming a front side transmissive region and a back side transmissive region with different sizes respectively (corresponding respectively to a narrow-spacing transmissive region on the front side of the base block 32 and a wide-spacing transmissive region on the back side of the base block 32) by adjusting exposure time or exposure intensity. d. first, coating the photoresist 31 on the front side of the base block 32, and performing the exposure and developing processes by using the second reticle plate 34, reserving the portion of the photoresist in the second reservation region, and removing the portion of the photoresist in the second removal region; e. next, dry etching the base block 32 to form a shape in which the middle and both ends are thinner while the slope portion is reserved, a notch 131 being formed in the thinner middle region; f. then, stripping the photoresist 31. Next, the previous step is repeated for the back side, i.e.: g. coating the photoresist 31 on the back side of the base block 32, and performing the exposure and developing processes by using the second reticle plate 34, during which a width of an opening is controlled by adjusting the exposure time or exposure intensity, so as to reserve a portion of the photoresist 31 in the second reservation region and remove a portion of the photoresist 31 in the second removal region; h. next, dry etching the base block 32 to form an opening 132 in the thinner middle region so that a pattern including the transmissive region 13 and the projection structure 12 is formed, obtaining a final appearance of the mask plate 1; i. then, stripping the photoresist 31.

In the method for manufacturing a mask plate, the shape of the photoresist directly affects the formation of the slope in the main body at a later stage. Since the slope formed after etching is consistent with the slope of the photoresist, the acquirement of the sheltering angle depends mainly on the photoresist process.

In an alternative manufacturing method, the mask plate may be formed by a method including a normal exposure process, a hard baking process and a dry etching process. As shown in FIG. 6B, in the step of forming the projection structure:

a. first, coating the photoresist 31 on the front side of the base block 32, and performing the exposure and developing processes by using the first reticle plate 33, reserving the portion of the photoresist 31 in a first reservation region, and removing the portion of the photoresist in a first removing region; al. making, by hard baking, an edge of the reserved photoresist shrink to form a slope to obtain a prototype with a shape that is thinner at both ends with an original thickness in the middle and is inclined from the middle to two ends, that is, changing an initial steep slope with a steep profile into a long slope with a mild profile by hard baking (see the second and the third sub-graphs); b. next, dry etching the base block 32 to form a sheltering-angle slope with both sides having a conformal shape as the photoresist; c. then, stripping the photoresist.

In the step of forming the transmissive region: processing, by typical processes for manufacturing a mask plate, the front and back sides of the base block 32, respectively, to form a front side transmissive region and a back side transmissive region with different opening. d. first, coating the photoresist 31 on the front side of the base block 32, and performing the exposure and developing processes by using the second reticle plate 34, reserving the portion of the photoresist in the second reservation region and removing the portion of the photoresist in the second removal region; e. next, dry etching the base block 32 to form a shape in which the middle and both ends are thinner while the slope portion is reserved, a notch 131 being formed in the thinner middle region; f. then, stripping the photoresist 31. Next, the previous step is repeated for the back side, i.e.: g. coating the photoresist 31 on the back side of the base block 32, and performing the exposure and developing processes by using the second reticle plate 34, reserving the portion of the photoresist 31 in the second reservation region and removing the portion of the photoresist 31 in the second removal region; h. next, dry etching the base block 32 to form an opening 132 in the thinner middle region so as to form a pattern including the transmissive region 13 and the projection structure 12 (to form the sheltering angle), obtaining a final appearance of the mask plate 1; i. then, stripping the photoresist 31.

The core of the manufacturing process is to make the profile of the photoresist steep by the hard baking process in which the parameters in the hard baking process are determined by reference to the design dimension of the sheltering angle, and then obtain the mask plate by the dry etching process.

In an alternative manufacturing method, the mask plate is formed by a method including a normal exposure process and a wet etching process. As shown in FIG. 6C, in the step of forming the projection structure:

a. first, coating the photoresist 31 on the front side of the base block 32, and performing the exposure and developing processes by using the first reticle plate 33, reserving the portion of the photoresist 31 in a first reservation region, and removing the portion of the photoresist in a first removing region, thereby forming a photoresist sheltering layer having a slope of steep profile; b′. next, wet etching the base block 32, wherein, since the wet etching process has the isotropic characteristic (that is, the etching direction has little relationship with the angle of the photoresist sheltering layer and the etching is performed at a constant rate in various directions), an arc-shaped bottom surface as shown in the third sub-graph is formed (in this case, the sheltering angle has a shape of curved triangle instead of a shape of rectilinear triangle), and thus regions at both sides of the base block 32 which are not covered by the photoresist are formed to have a arc-shaped surface; c. then, stripping the photoresist.

In the step of forming the transmissive region: processing, by typical processes for manufacturing a mask plate, the front and back sides of the base block 32, respectively, to form a front side transmissive region and a back side transmissive region with different openings. d. first, coating the photoresist 31 on the front side of the base block 32, and performing the exposure and developing processes by using the second reticle plate 34, reserving the portion of the photoresist in the second reservation region and removing the portion of the photoresist in the second removal region; e′. next, wet etching the base block 32, forming, by isotropic etching, a shape in which the middle and both ends are thinner while the slope portion is reserved, a notch 131 being formed in the thinner middle region; f. then, stripping the photoresist 31. Next, the previous step is repeated for the back side, i.e.: g. coating the photoresist 31 on the back side of the base block 32, and performing the exposure and developing processes by using the second reticle plate 34, reserving the portion of the photoresist in the second reservation region, and removing the portion of the photoresist in the second removal region; h′. next, wet etching the base block 32, forming an middle opening 132 by isotropic etching so as to obtain a pattern including the transmissive region 13 and the projection structure 12, thus obtaining a final appearance of the mask plate 1; i. then, stripping the photoresist 31. In comparison, the photoresist formed by this process has a steeper profile than that of the photoresist obtained by the hard baking process.

Combining the above three alternative manufacturing methods, after the step of making the projection structure extend to the transmissive region and suspend above the transmissive region:

the step of removing a transmissive region section of the base block corresponding to the transmissive region where no projection structure is provided, and reserving a part of the base block corresponding to the projection structure and the shading region includes:

performing a front-side patterning process on a side of the base block on which the projection structures are formed, so as to form a notch which is limited by the spacing between opposite projection structures. Optionally, the thickness of the base block at the bottom of the notch is no greater than that of the main body. That is to say, during the front-side patterning process, the portion of the base block corresponding to the transmissive region may not be penetrated through, but still has a certain thickness which may be removed in a back-side patterning process;

performing the patterning process on a back side of the base block on which no projection structure is formed, so as to form an opening which is limited by the spacing between opposite edges of the main body. Since the size of the opening is greater than that of the notch, the middle portion of the base block corresponding to the notch can be effectively removed to achieve the effect that the projection structures are arranged in a suspended manner in the transmissive region.

According to the method for manufacturing a mask plate provided by the present embodiment, it is easy to form a mask plate capable of effectively preventing the broken deposits generated in the vapor deposition process from falling and contaminating the substrate, thus reducing the deposition shadow, and improving the performance of film layers; meanwhile, the replacement time of the mask plate within an evaporation cycle is prolonged, which further improving the productivity and reducing the cost.

### Second Embodiment

The present embodiment provides a mask plate and a method for manufacturing a mask plate. The mask plate can effectively block the peeling-off deposits generated in the vapor deposition process, ensure the quality of the finished products, and prolong the clean cycle.

As for film layer encapsulation structure with a normal bezel, reduction of the deposition shadow and the peeling-off deposits may be achieved at the expense of the pixel aperture ratio. However, as for a film layer encapsulation structure with a narrow bezel, the pixel aperture ratio has to be guaranteed. The present embodiment is suitable for a mask plate with a narrow bezel. In the present embodiment, only a projection structure 12 is provided, which does not extend to the transmissive region. Generally, the greater the maximum height of the projection structure 12 is, the larger the sheltering angle is and the smaller the deposition angle is. However, it is known from the actual experience that the sheltering angle is limited. If the sheltering angle is too high, the encapsulation film layer will be deposited at the right-angle corner of the sheltering angle. Therefore, as for a normal bezel, comprehensive considerations may be made from the two aspects, i.e., the loss of pixel aperture ratio and avoiding a too high sheltering angle. Meanwhile, it should be appreciated that, decreasing the pixel aperture ratio is just to avoid a too high sheltering angle. In the practice, whether the aperture ratio needs to be changed is determined according to processes in different factories.

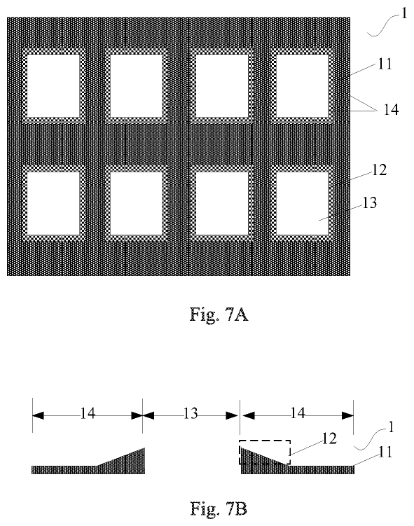

As shown in FIGS. 7A and 7B, a mask plate 1 is divided into at least a transmissive region 13 and at least a shading region 14, wherein the mask plate includes a main body 11, and a projection structure 12 is disposed at an edge of the shading region adjacent to the transmissive region in a direction perpendicular to the main body 11. A height of the projection structure 12 near the transmissive region is greater than that of the projection structure 12 away from the transmissive region.

Accordingly, the present embodiment further provides a method for manufacturing a mask plate so as to manufacture a mask plate in vapor deposition process. Similar to the first embodiment, the mask plate in the present embodiment may be formed by three methods, respectively. However, since the projection structure 12 does not extend in a suspended manner to the transmissive region, the steps of coating the back side of the base block 32 and performing patterning are omitted. Thus, the process is simplified.

The method for manufacturing a mask plate includes a step of forming the transmissive region 13 and the shading region 14 in the main body 11. In method for manufacturing a mask plate, a projection structure 12 is formed at an edge of the shading region 14 adjacent to the transmissive region 13 in the direction perpendicular to the main body 11, and a height of the projection structure 12 near the transmissive region 13 is greater than that away from the transmissive region 13.

In an alternative manufacturing method, the mask plate 1 may be manufactured by using a method including a semi-exposure process and a dry etching process as well as a normal exposure process, that is, a first exposure process is the semi-exposure process in which a gray-tone reticle plate or a half-tone reticle plate is used. A section corresponding to the transmissive region 13 is a first complete-reservation region, a section corresponding to the projection structure 12 is a half-reservation region, and a section corresponding to the shading region 14 is a first complete-removal region. The half-reservation region has a transmittance which changes gradually from the first complete-reservation region to the first complete-removal region. In the normal reticle plate used in the second exposure process, a section corresponding to the transmissive region 13 is a second removal region, and a section corresponding to the projection structure 12 and the shading region 14 is a second reservation region.

Similarly, the terms “reservation region” and “removal region” are termed in regard to whether the photoresist formed therein during a coating process is reserved or removed in a final state, regardless of the properties of the photoresist (negative photoresist or positive photoresist); generally, the negative photoresist is reserved while the positive photoresist is removed after the exposure and developing processes.

As for the mask plate in the present embodiment, the manufacturing method thereof also includes two processes of forming the projection structure and forming the transmissive region. Compared with the mask plate in the first embodiment, here only the front-side patterning process is required to form the transmissive region, and the opening of the transmissive region is formed directly, thus resulting in a simplified process.

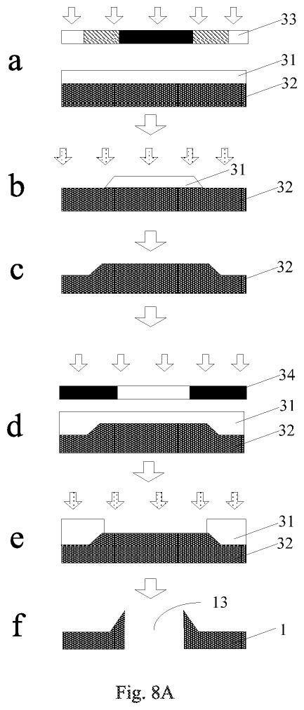

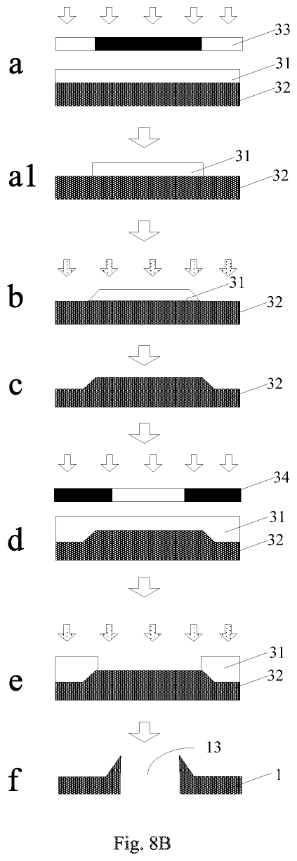

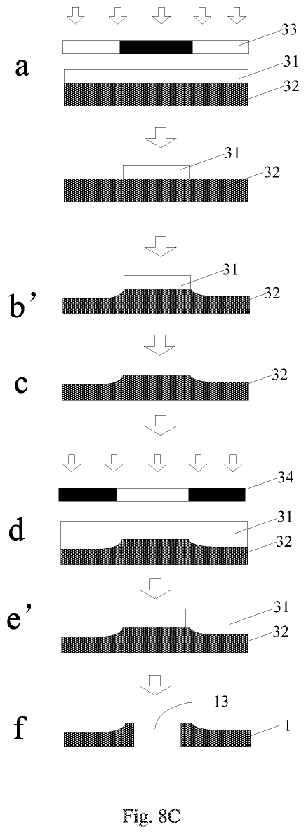

As shown in FIG. 8A, a. first, coating the photoresist 31 on the front side of the base block 32, and performing exposure process by using the first reticle plate 33, i.e., a half-tone or gray-tone reticle plate, reserving the portion of the photoresist 31 in the first complete-reservation region, removing the portion of the photoresist 31 in the first complete-removal region, and making the portion of the photoresist 31 in the half-reservation region form a slope with a thickness decreasing gradually from an initial thickness to zero, and thus achieving a long slope with a mild profile; b. then, dry etching the base block 32 to obtain a prototype with a shape that in thinner at both ends with an original thickness in the middle and is inclined from the middle to two ends, and thus forming a sheltering-angle slope having a conformal profile as the profile of the photoresist; c. then, stripping the photoresist 31. d. next, coating the photoresist 31 on the front side of the base block 32, and performing exposure and developing processes by using the second reticle plate 34, reserving the portion of the photoresist in the second reservation region, and removing the portion of the photoresist in the second removal region; e. dry etching the base block 32 to form a shape in which the middle and both ends are thinner while the slope portion is reserved, thereby forming a pattern including the transmissive region 13 and the projection structure 12, and obtaining a final appearance of the mask plate 1; f. then, stripping the photoresist 31. In this method for manufacturing a mask plate, the shape of the photoresist directly affects the formation of the slope in the main body at a later stage. Since the slope formed after etching is consistent with the slope of the photoresist, the acquirement of the sheltering angle depends mainly on the photoresist process.

In an alternative manufacturing method, the mask plate 1 is formed by a method including a normal exposure process, a hard baking process and a dry etching process. As shown in FIG. 8B, a. coating the photoresist 31 on the front side of the base block 32, and performing the exposure and developing processes by using the first reticle plate 33, reserving the portion of the photoresist 31 in the first reservation region, and removing the portion of the photoresist in the first removing region; a′. making, by hard baking in the exposure process, an edge of the reserved photoresist shrink to form a slope to obtain a prototype with a shape that is thinner at both ends with an original thickness in the middle and is inclined from the middle to two r ends, that is, making an initial steep slope with a steep profile become a long slope with a mild profile by hard baking (see the second and the third sub-graphs); b. next, processing the base block 32 by dry etching to form a sheltering slope with both sides conformal to the shape of the photoresist; c. stripping the photoresist. Next, typical processes for manufacturing a mask plate are used. d. coating the photoresist 31 on the front side of the base block 32, and performing the exposure and developing processes by using the second reticle plate 34, reserving the portion of the photoresist in the second reservation region, and removing the portion of the photoresist in the second removal region; e. dry etching the base block 32 to form a shape in which the middle and both ends are thinner while the slope portion is reserved, thereby forming a pattern including the transmissive region 13 and the projection structure 12 (i.e. the sheltering angle), and obtaining a final appearance of the mask plate 1; f. stripping the photoresist 31. The core of this manufacturing process is to make the profile of the photoresist steeper by the hard baking process, wherein the parameters in the hard baking process are determined by reference to the design dimension of the sheltering angle, and then the mask plate is achieved by the dry etching process.

In an alternative manufacturing method, the mask plate 1 is formed by a method including a normal exposure process and a wet etching process. As shown in FIG. 8C, a. coating the photoresist 31 on the front side of the base block 32, and performing the exposure and developing processes by using the first reticle plate 33, reserving the portion of the photoresist 31 in the first reservation region, and removing the portion of the photoresist in the first removing region, thereby forming a photoresist sheltering layer having a slope of steep profile; b′. next, wet etching the base block 32, wherein, since the wet etching process has the isotropic characteristic (that is, the etching direction has little relationship with the angle of the photoresist sheltering layer and the etching is performed at a constant rate in various directions), an arc-shaped surface as shown in the third sub-graph is formed (in this case, the sheltering angle has a shape of curved triangle instead of a shape of rectilinear triangle), and thus regions at both sides of the base block 32 which are not covered by the photoresist are formed to have a arc-shaped surface; c. then, stripping the photoresist. Next are the typical processes for manufacturing a mask plate. d. coating the photoresist 31 on the front side of the base block 32, and performing the exposure and developing processes by using the second reticle plate 34, reserving the portion of the photoresist in the second reservation region, and removing the portion of the photoresist in the second removal region; e′. wet etching the base block 32, forming, by isotropic etching, a shape in which the middle and both ends are thinner while the slope portion is reserved, thereby forming a pattern including the transmissive region 13 and the projection structure 12, and obtaining a final appearance of the mask plate 1; f. stripping the photoresist 31. In comparison, the photoresist formed by this process has a steeper angle than that of the photoresist obtained by the hard baking process.

According to the method for manufacturing a mask plate provided by the present embodiment, it is easy to form a mask plate capable of effectively preventing the broken deposits generated in the vapor deposition process from falling and contaminating the substrate, thus reducing the deposition shadow, and improving the performance of film layers; meanwhile, the replacement time of the mask plate within an evaporation cycle is prolonged, which further improving the productivity and reducing the cost. Such mask plate is particularly suitable for manufacturing an encapsulation structure of a display panel with a narrow bezel.

### Third Embodiment

The present embodiment provides an encapsulation structure which is formed by a mask plate provided by the first embodiment or the second embodiment.

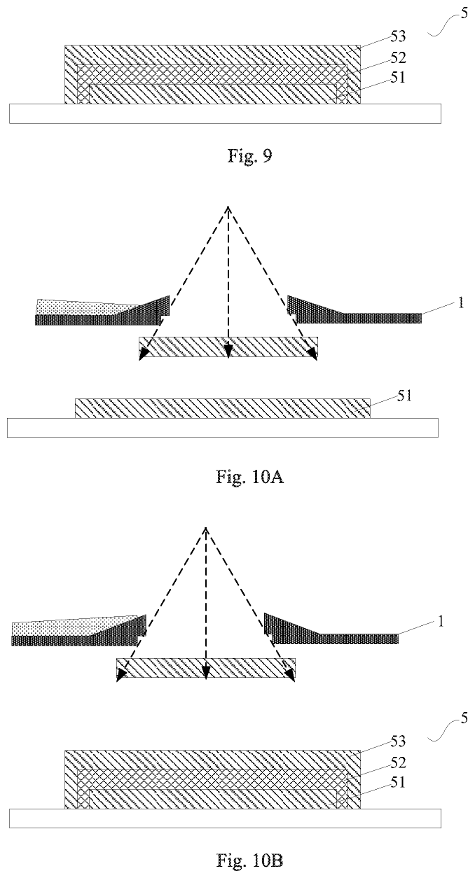

In a case of a same deposition shadow, the encapsulation structure 5 in the present embodiment can, by adjusting the height of the sheltering angle and controlling the deposition direction of large angle, achieve an accelerated CVD at the encapsulation region, reduce the deposition shadows of the first inorganic film layer and the second inorganic film layer, and effectively control the risk related to the film layer shadow. The resulting encapsulation structure is shown in FIG. 9. For example, according to a domestic manufacturer of display products, a thickness of the film below the boundary of the transmissive region is about 80% of a target thickness, and a distance between a boundary of the mask plate and a boundary of inorganic film layers is about 360 μm.

In this encapsulation structure, since the distance for the second inorganic film layer enclosing a shadow of the first inorganic film layer is increased, the offset for process alignment is also increased, achieving an increased margin. Thus, the alignment margin for aligning the first and the second inorganic film layers is further improved without changing the aperture ratio, improving the reliability of the thin film encapsulation, especially the encapsulation for side bezel.

### Fourth Embodiment

The present embodiment provides a method for forming a film layer, which can manufacture the encapsulation structure of the third embodiment, especially an encapsulation suitable for an OLED display device.

In the method for forming a film layer, a first inorganic film layer, an organic film layer and a second inorganic film layer are formed by vapor deposition process. In the processes for manufacturing the encapsulation structure, the larger the sheltering angle of the mask plate (i.e., the higher the sheltering triangle) is, the smaller the deposition angle is. Therefore, by adjusting the sheltering angles of mask plates for different film layers, it is achieved that a deposition angle of the second inorganic film layers can enclose a deposition angle of the first inorganic film layer.

As for an encapsulation structure for a normal bezel, the method for forming a film layer includes the following steps:

forming a first inorganic film layer 51 by using a first mask plate, as shown in FIG. 10A, the first mask plate being provided with a first projection structure at an edge of a shading region 14 adjacent to a transmissive region 13 in a direction perpendicular to a main body 11; and the portion of the first projection structure adjacent to the transmissive region is suspended above the transmissive region;

forming an organic film layer 52;

forming a second inorganic film layer 53 by using a second mask plate, as shown in FIG. 10B, the second mask plate being provided with a second projection structure at an edge of a shading region 14 adjacent to a transmissive region 13 in a direction perpendicular to a main body 11; and the portion of the second projection structure adjacent to the transmissive region is suspended above the transmissive region.

Optionally, a maximum height of the first projection structure is greater than that of the second projection structure. That is, the height of the projection structure in the mask plate for forming the first inorganic film layer 51 is made to be greater than that of the projection structure in the mask plate for forming the second inorganic film layer 53, thereby forming mask plates which block the broken deposits generated in vapor deposition process to different degrees.

Optionally, in a direction from the shading region to the transmissive region, an extension distance of an extension portion of each of the first and the second projection structures which is suspended above the transmissive region ranges from ¼ to ½ of a total dimension of the corresponding projection structure in the same direction. For example, the extension distance of the extension portion is set to 350 to 650 μm. By adjusting an extension distance of the extension portion, the projection structure can achieve a compromise between sheltering effect and receiving effect.

Optionally, a cross section of each of the first and the second projection structures in a plane perpendicular to the plane of the main body 11 has a shape of a triangle or a trapezoid.

In the method for forming a film layer, by providing a first projection structure and a second projection structure different from each other in the mask plates for forming different inorganic film layers, respectively, the deposits peeling off from respective inorganic film layers during vapor deposition process are blocked accordingly, which ensures the quality of the finished products, and prolongs the clean cycle. Thus, the method in the present embodiment can apply to an encapsulation structure with a normal bezel and a narrow bezel.

As for an encapsulation structure for a narrow bezel, the method for forming a film layer includes the following steps:

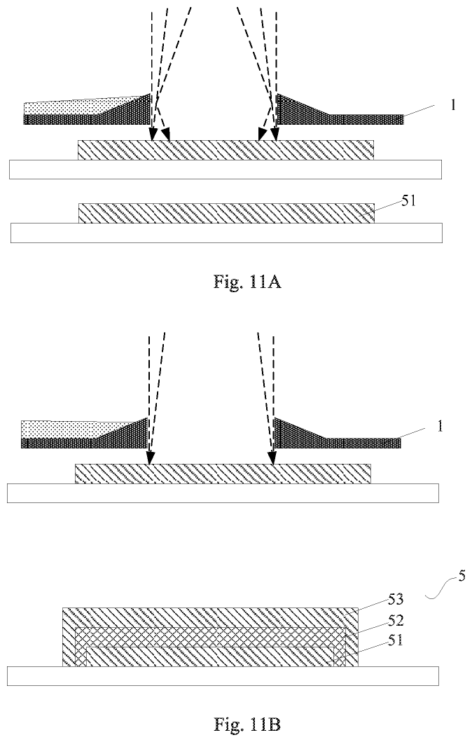

forming a first inorganic film layer 51 by using a first mask plate, as shown in FIG. 11A, the first mask plate being provided with a first projection structure at an edge of a shading region 14 adjacent to a transmissive region 13 in a thickness direction;

forming an organic film layer 52;

forming a second inorganic film layer 53 by using a second mask plate, as shown in FIG. 11B, the second mask plate being provided with a second projection structure at an edge of a shading region 14 adjacent to a transmissive region 13 in the thickness direction;

Here, it is only required that the height of each of the first and the second projection structures near the transmissive region is greater than that away from the transmissive region, and the first and the second projection structures do not need to be suspended above the transmissive region.

Since the size of the transmissive region does not affect the size of the shadow, a film thickness in the shadow area cannot be ensured, that is, the encapsulation performance is not ensured. According to a domestic manufacturer of display products, the size of a shadow of a film layer in thin film encapsulation is about 400 μm, and the size of a region which has a thickness less than 70% of the film thickness and the encapsulation performance cannot be ensured is greater than 300 μm. Since the size range of the bezel in an existing display product is about 800 to 1100 μm, along with about 100 μm of the manufacturing tolerance of a mask plate and about 50 μm of the alignment error, the encapsulation performance cannot be ensured. As a result, it is very difficult to reduce the pixel aperture ratio even by 100 μm. On the contrary, according to the method for forming a film layer in the present embodiment, the size of the region in which the film thickness in the shadow cannot be ensured can be reduced from 300 μm to 150 μm. This effect is very beneficial for the thin film encapsulation.

In the method for forming a film layer, by using a mask plate in which the height of the sheltering angle is designed to be able to control the vapor deposition shadow, the range of the deposition shadow is adjusted by adjusting a height of a projection structure so that the deposition angle is matched with the sheltering angle of the thin film encapsulation structure (TFE), thus preventing effectively the peeling-off deposits in a non-opening region from contaminating the glass; moreover, by employing different sheltering angles for the first and the second inorganic film layers, an encapsulation with an enclosing effect of that the second inorganic film layer encloses the first inorganic film layer is achieved, improving the reliability of the encapsulation; thus, it is possible to reduce the mask plate replacement frequency, prolong the process time of the mask plate in one evaporation cycle effectively, improve the productivity and save the cost.

It will be appreciated that the above implementations are only exemplary implementations for illustrating the principle of the present disclosure. However, the present disclosure is not limited thereto. An ordinary person skilled in the art can make various modifications and improvements to the present disclosure without departing from the essence of the present disclosure. These modifications and improvements should be also considered as the protective scope of the present disclosure.

1. A mask plate, which is divided into at least a transmissive region and a shading region, wherein,
the mask plate comprises a main body and a projection structure disposed on the main body at an edge of the shading region adjacent to the transmissive region; and
the projection structure protrudes away from the main body, and a thickness of the projection structure in a direction perpendicular to a plane of the main body decreases gradually in a direction from the transmissive region to the shading region.

2. The mask plate of claim 1, wherein a cross section of the projection structure in a plane perpendicular to the plane of the main body and in a direction from the transmissive region to the shading region has a shape of a triangle or a trapezoid.

3. The mask plate of claim 1, wherein the projection structure comprises a slope in the direction from the transmissive region to the shading region on a plane perpendicular to the plane of the main body, the slope being a smooth curved surface.

4. The mask plate of claim 1, wherein the projection structure further comprises a flat portion adjacent to the transmissive region, and a thickness of the flat portion is a maximum thickness of the projection structure.

5. The mask plate of claim 1, wherein the projection structure extends towards the transmissive region to form an extension portion which is suspended above the transmissive region.

6. The mask plate of claim 1, wherein the projection structure extends towards the transmissive region to form an extension portion which comprises two slopes in a direction from the shading region to the transmissive region on a plane perpendicular to the plane of the main body.

7. The mask plate of claim 6, wherein the two slopes are two curved surfaces which are symmetrical in relative to a plane parallel to the plane of the main plane.

8. The mask plate of claim 5, wherein, in a direction from the shading region to the transmissive region, a size of the extension portion of the projection structure which is suspended above the transmissive region ranges from ¼ to ½ of a total size of the projection structure in this direction.

9. A method for manufacturing a mask plate, which is divided into at least a transmissive region and a shading region, wherein the mask plate comprises a main body and a projection structure disposed on the main body at an edge of the shading region adjacent to the transmissive region; and the projection structure protrudes away from the main body, and a thickness of the projection structure in a direction perpendicular to a plane of the main body decreases gradually in a direction from the transmissive region to the shading region, the method comprising:
dividing a base block into at least a transmissive region section corresponding to the transmissive region of the mask plate and a shading region section corresponding to the shading region of the mask plate;
performing a first patterning process on the base block such that a height of the transmissive region section is greater than a height of a part of the shading region section where the projection structure is not to be disposed and the base block has a slope structure which is tapered from the transmissive region section to the part of the shading region section where the projection structure is not to be disposed; and
removing at least a part of the transmissive region section by a second patterning process.

10. The method of claim 9, wherein the step of removing at least a part of the transmissive region section by a second patterning process comprises completely removing the transmissive region section by the second patterning process.

11. The method of claim 9, wherein the first patterning process comprises:
coating photoresist on a front side of the base block and performing exposing and developing on the photoresist by using a gray-tone reticle plate or a half-tone reticle plate to reserve a portion of the photoresist in a first complete-reservation region corresponding to the transmissive region section, remove a portion of the photoresist in a first complete-removal region corresponding to the part of the shading region section where the projection structure is not to be disposed, and cause a portion of the photoresist in a half-reservation region corresponding to the projection structure to form a slope with a thickness decreasing gradually from an initial thickness of the photoresist in the first complete-reservation region to zero;
performing a dry etching process on the base block to obtain a shape having a thickness which is the initial thickness in a middle, thinner at two ends and inclined from the middle to the two ends; and
removing the photoresist on the base block.

12. The method of claim 9, wherein the first patterning process comprises:
coating photoresist on a front side of the base block and performing exposing and developing on the photoresist by using a first reticle plate to reserve a portion of the photoresist in a first reservation region corresponding to the transmissive region of the mask plate and remove a portion of the photoresist in a first transmissive region corresponding to the shading region of the mask plate;
performing a hard baking process on the photoresist such that an edge of the reserved portion of the photoresist shrinks to form a slope so as to obtain a shape having a thickness which is an original thickness of the photoresist in a middle, thinner at two ends and inclined from the middle to the two ends;
dry etching the base block; and
removing the photoresist.

13. The method of claim 9, wherein the first patterning process comprises:
coating photoresist on a front side of the base block and performing exposing and developing on the photoresist by using a first reticle plate to reserve a portion of the photoresist in a first reservation region corresponding to the transmissive region of the mask plate and remove a portion of the photoresist in a first removal region corresponding to the shading region of the mask plate;
performing a wet etching process on the base block so that portions of the base block at the first removal region have arc-shaped surfaces, respectively; and
removing the photoresist.

14. The method of claim 9, wherein the second patterning process comprises: making a part of the base block corresponding to the transmissive region remain a thickness less than or equal to a thickness of the main body; then performing a third patterning process on a backside surface of the base block on which the projection structure is not formed to completely remove the part of the base block corresponding to the transmissive region.

15. The method of claim 14, both the second patterning process and the third patterning process comprise a wet etching process.

16. The method of claim 15,
wherein the second patterning process comprises: forming a notch which has a size along an extension direction of the main body which is obtained by subtracting extension distances of two opposite projection structures extending into the transmissive region from a span of the transmissive region along the extension direction of the main body, and
the third patterning process comprises: forming an opening having a size of the span of the transmissive region along the extension direction of the main body such that the projection structure extends to the transmissive region and is partially suspended above the transmissive region.

17. A method for forming a film layer in an encapsulation structure, and the film layer comprising a first inorganic film layer and a second inorganic film layer which are formed by a chemical vapor deposition process, the method comprising steps of:
forming the first inorganic film layer by using a first mask plate which is divided into at least a first transmissive region and a first shading region, and has a first main body and a first projection structure disposed at an edge of the first shading region adjacent to the first transmissive region and extending in a direction perpendicular to a plane of the first main body;
forming an organic film layer; and
forming the second inorganic film layer by using a second mask plate which is divided into at least a second transmissive region and a second shading region, and has a second main body and a second projection structure disposed at the edge of the second shading region adjacent to the second transmissive region and extending in the direction perpendicular to the plane of the second main body;
wherein a height of a part of the first projection structure near the first transmissive region is greater than that of a part of the first projection structure away from the first transmissive region, and a height of a part of the second projection structure near the second transmissive region is greater than that of a part of the second projection structure away from the second transmissive region.

18. The method of claim 17, wherein a maximum height of the first projection structure is greater than that of the second projection structure.

19. The mask plate of claim 2, wherein the projection structure extends towards the transmissive region to form an extension portion which is suspended above the transmissive region.

20. The mask plate of claim 3, wherein the projection structure extends towards the transmissive region to form an extension portion which is suspended above the transmissive region.
